(19) United States
(12) Patent Application Publication
(10) Pub. No.: US 2024/0275199 A1
(43) Pub. Date: Aug. 15, 2024

(54) Battery Cluster Topology And Control Method Of Battery Cluster For Lithium-ion Battery Energy Storage System

(71) Applicant: Vilion (Shenzhen) New Energy Technology Co., Ltd., Shenzhen (CN)

(72) Inventors: Shawn SONG, Shenzhen (CN); Dias ZHANG, Shenzhen (CN); Ivan TAN, Shenzhen (CN)

(21) Appl. No.: 18/416,637

(22) Filed: Jan. 18, 2024

(30) Foreign Application Priority Data
Feb. 12, 2023 (CN) 202310100433.3

(51) Int. Cl. H02J 7/00; G01R 31/3835; H01M 10/0525; H01M 10/42; H01M 10/44; H01M 10/48; H01M 50/509

(52) U.S. Cl. CPC H02J 7/00712; G01R 31/3835; H01M 10/0525; H01M 10/425; H01M 10/441; H01M 10/482; H01M 50/509; H02J 7/00032; H02J 7/00304; H02J 7/0047; H01M 2010/4271; H01M 2010/4278; H02J 2207/20

(57) ABSTRACT

The present invention provides a battery cluster topology for a lithium-ion battery energy storage system and a control method of battery cluster therefor. The battery cluster parallel topology for the lithium-ion battery energy storage system includes at least two parallel battery cluster units, and the battery cluster unit is composed of N battery packs (N is a natural number greater than or equal to 2), N bidirectional DC/DC voltage conversion modules, N bypass switches, BDCM coordination controller units, circuit switches, and primary buses for connection.

### CROSS-REFERENCE TO RELATED APPLICATION

This application claims the priority of Chinese Patent Application No. 202310100433.3, entitled “Battery Cluster Topology And Control Method Of Battery Cluster For Lithium-ion Battery Energy Storage System” filed on Feb. 12, 2023 in the National Intellectual Property Administration of China, the whole disclosure of which is incorporated herein by reference.

### TECHNICAL FIELD

The present invention relates to technical field of a lithium-ion battery energy storage system, in particular to a battery cluster topology and a control method of battery cluster suitable for a lithium-ion battery energy storage system.

### BRIEF DESCRIPTION OF THE RELATED ART

On Sep. 22, 2020, the Chinese government proposed a goal at the 75^{th} United Nations General Assembly that China will increase its nationally determined contributions, adopt more powerful policies and measures, strive to peak carbon dioxide emissions before 2030, and strive to achieve carbon neutrality before 2060. Energy storage technology is one of the key technologies to achieve this goal, and lithium-ion battery energy storage technology has attracted much attention as the most widely used electrochemical energy storage technology. At the same time, our country has become the world's largest new energy vehicle market. After 2020, a large number of lithium-ion power batteries in our country will gradually begin to be retired. There are currently two main processing paths for these retired batteries. One is for those that are not scrapped but have reduced capacity and cannot be used in electric vehicles, to be utilized step by step to allow them to use their waste heat in other areas (such as power storage); and the other one is to dismantle scrapped power batteries and recycle valuable materials.

With reference to whether retired batteries or new batteries, there are performance inconsistencies due to health status, internal resistance, self-discharge and other factors. However, large and medium-sized lithium-ion battery energy storage systems generally consist of multiple battery clusters connected in series or parallel or a mixed connection thereof. The battery cluster is composed of multiple battery packs connected in series, parallel, or a mixed connection thereof, while the battery pack is composed of multiple single cells connected in series, parallel, or a mixed connection thereof. The performance inconsistency of the single battery will inevitably lead to inconsistency in battery packs and battery clusters, thereby affecting the performance of battery packs and battery clusters. In serious cases, it may lead to safety accidents.

In the application of maintenance and replacement of old and new batteries, and the replacement of lead-acid batteries by lithium-ion batteries, due to the inconsistency in battery types and performance status, the existing solution must replace the entire battery cluster or the entire battery pack, which is a big waste of battery resources and increases the cost.

In parallel applications of multiple battery clusters, when the battery types and performance status between battery clusters are inconsistent, it will cause inrush current and return current between battery clusters. In severe cases, it will lead to battery overcharge, over-discharge and other safety issues. This should be avoided in energy storage system integration.

Therefore, it seems very necessary how to reduce the component cost or maintenance and replacement cost of the lithium-ion battery energy storage system, improve system efficiency, and improve safety and reliability, from the comprehensive dimensions of the topology, the control method, and control strategy of the lithium-ion battery energy storage system.

### SUMMARY OF THE DISCLOSURE

The technical problem to be solved by the present invention is to overcome the above-mentioned defects of the prior art and provide a battery cluster topology and a control method of battery cluster suitable for a lithium-ion battery energy storage system.

The present invention is achieved by the following solutions.

A battery cluster topology for a lithium-ion battery energy storage system, the battery cluster topology for the lithium-ion battery energy storage system comprises P parallel battery cluster units (P is a natural number greater than or equal to 2), each battery cluster unit is composed of N battery packs (N is a natural number greater than or equal to 2), N bidirectional DC/DC voltage conversion modules, N bypass switches, BDCM coordination controller units, circuit switches and primary buses for connection.

Output ends of the N bidirectional DC/DC voltage conversion modules are connected in series in sequence, a negative output end of the first bidirectional DC/DC voltage conversion module is connected with a negative electrode of the primary bus, and a positive output end of the first bidirectional DC/DC voltage conversion module is connected with a negative output end of the second bidirectional DC/DC voltage conversion module, a positive output end of the second bidirectional DC/DC voltage conversion module is connected with a negative output end of the third bidirectional DC/DC voltage conversion module, and a positive output end of (N−1)^{th} bidirectional DC/DC voltage conversion module is connected with a negative output end of the N^{th} bidirectional DC/DC voltage conversion module, and a negative output end of the N^{th} bidirectional DC/DC voltage conversion module is connected with one end of the circuit switch, and the other end of the circuit switch is connected with a positive electrode of the primary bus.

The N battery packs are connected in parallel with input ends of the N bidirectional DC/DC voltage conversion modules, a positive end of the first battery pack is connected with a positive input end of the first bidirectional DC/DC voltage conversion module, and a negative end of the first battery pack is connected with a negative input end of the first bidirectional DC/DC voltage conversion module, a positive end of the N^{th} battery pack is connected with a positive input end of the N^{th} bidirectional DC/DC voltage conversion module, and a negative end of the N^{th} battery pack is connected with a negative input end of the N^{th} bidirectional DC/DC voltage conversion module.

The N bypass switches are connected in parallel with output ends of the N bidirectional DC/DC voltage conversion modules, one end of the first bypass switch is connected with the negative output end of the first bidirectional DC/DC voltage conversion module, the other end of the first bypass switch is connected with the positive output end of the first bidirectional DC/DC voltage conversion module, one end of the N^{th} bypass switch is connected with the negative output end of the N^{th} bidirectional DC/DC voltage conversion module, and the other end of the N^{th} bypass switch is connected with the positive output end of the N^{th} bidirectional DC/DC voltage conversion module.

The bidirectional DC/DC voltage conversion module integrates functions of the battery management unit BMU, which can calculate a state of charge, estimate a health status, and manage safety of the battery pack for the battery pack, and the bidirectional DC/DC voltage conversion modules regulate its output voltage according to instructions of the BDCM coordination controller units.

The bypass switches function as the bypass bidirectional DC/DC voltage conversion modules.

The BDCM coordination controller units manage the battery cluster, having functions of charging and discharging management of the battery cluster, calculation of the state of charge of the battery cluster, safety management of the battery cluster, controlling the bypass switches to close or open, and controlling the circuit switches to close or open, and having a function of communicating and information interaction with the outside.

The battery pack consists of two or more single lithium-ion batteries connected in series.

The BDCM coordination controller unit is connected with the bidirectional DC/DC voltage conversion module, the bypass switch, and the circuit switch through the communication bus, and the battery management unit BMU of the bidirectional DC/DC voltage conversion module is communicatively connected with an underlying management unit of the battery pack.

The control method of battery cluster includes calculating the total target voltage of the battery cluster, starting a process control, and stopping the process control.

The step of calculating the total target voltage of battery cluster in the control method of battery cluster is as follows:
Step 1, the n^{th} BDCM coordination controller unit reads current voltages of all N battery packs in the n^{th} battery cluster unit, and adds voltages of the N battery pack to obtain the total voltage V_total_n of the n^{th} battery cluster unit, n being a natural number from 1 to P.
Step 2, each BDCM coordination controller unit broadcasts the total voltage of a corresponding battery cluster unit on its communication bus, each BDCM coordination controller unit compares the total voltage of the battery cluster unit of this battery cluster unit with those of the battery cluster units among other battery cluster units, and each BDCM coordination controller unit broadcasts the maximum value of total voltage of the battery cluster in the battery cluster unit determined by itself on its communication bus.
Step 3, each BDCM coordination controller unit receives the maximum value of the total voltage of the battery cluster broadcast on the communication bus, and compares these results with the maximum value of the total voltage of the battery cluster determined by itself, if the results are different, then it returns to the step 1 and calculates again; or if the results are the same, then it calculates the total target voltage of the battery cluster, the total target voltage of n^{th} battery cluster is V_target_cluster_n, V_target_cluster_n=V_max_cluster+V_con, where the V_max_cluster is the maximum value of the total voltage of the battery clusters in all P battery cluster units, n is a natural number from 1 to P, V_con is a fixed limit value, and the value of V_con satisfies: V_con≤V_DC_sum−V_max_cluster, where V_DC_sum is a sum of the limit values of the output voltages of all bidirectional DC/DC voltage conversion modules in the battery cluster which has a maximum value of the total voltage of the battery cluster.

The step of starting process control in the control method of battery cluster is as follows:
Step 1, the n^{th} BDCM coordination controller unit reads the information of the battery pack and the bidirectional DC/DC voltage conversion module of the n^{th} battery cluster unit, including the state of charge of the battery pack, the voltage of the battery pack, temperature of the battery pack, and fault information of the bidirectional DC/DC voltage conversion module.
Step 2, the n^{th} BDCM coordination controller unit determines consistency of the status of all N battery packs in the n^{th} battery cluster unit.
Step 3, if the consistency of the battery pack status of the n^{th} battery cluster unit meets requirements, the n^{th} BDCM coordination controller unit broadcasts the output voltage V_out_n of all bidirectional DC/DC voltage conversion modules of the n^{th} battery cluster on the communication bus, and V_out_n=V_target_cluster_n/m, m is the number of all fault-free battery packs in the n^{th} battery cluster; if the consistency of the battery pack status of the n^{th} battery cluster unit does not meet the requirements, then the k^{th} bidirectional DC/DC voltage conversion module of the n^{th} battery cluster has a discharge output voltage V_dis_out_nk=V_target_cluster_n×SOCₙₖ/Σᵢ₌₁^{m}SOCₙᵢ, the k^{th} bidirectional DC/DC voltage conversion module of the n^{th} battery cluster has a charging output voltage V_ch_out_nk=V_target_cluster_n×(1−SOCₙₖ)÷(m−Σᵢ₌₁^{m}SOCₙᵢ), where SOCₙₖ is the charge ratio of the k^{th} battery pack of the n^{th} battery cluster, and m is the number of all fault-free battery packs of the n^{th} battery cluster, Σᵢ₌₁^{m}SOCₙᵢ represents the sum of the charge ratios of all m fault-free battery packs in the n^{th} battery cluster, obviously, m≤P.
Step 4, if the output voltage of b bidirectional DC/DC voltage conversion modules in the n^{th} battery cluster exceeds the limit value (assuming the limit value is V_out_limit), the n^{th} BDCM coordination controller unit controls the output voltage of the bidirectional DC/DC voltage conversion module to be V_out_limit, all other bidirectional DC/DC voltage conversion modules in the n^{th} battery cluster have an output voltage V_out_n=(V_target_cluster_n−V_out_limit)÷(m−b), where m is the number of all fault-free battery packs in the n^{th} battery cluster, and b is a natural number from 1 to m.
Step 5, the n^{th} BDCM coordination controller unit determines whether the total voltage of the n^{th} battery cluster unit reaches the total target voltage V_target_cluster_n of the n^{th} battery cluster or not, if not, it returns to the step 1, if it does, it proceeds to the charging or discharging phase. In the above steps 1 to 5, n is a natural number from 1 to P, and P is the number of battery clusters.

The step of stopping the process control in the control method of battery cluster is as follows:
Step 1, if the n^{th} BDCM coordination controller unit detects that the r^{th} battery pack of the n^{th} battery cluster unit fails, or the r^{th} battery pack reaches the charge cut-off condition, or the r^{th} battery pack reaches the discharge cut-off condition, or the r^{th} bidirectional DC/DC voltage conversion module fails, it proceeds to the next step.
Step 2, the n^{th} BDCM coordination controller unit controls the output voltage of the r^{th} bidirectional DC/DC voltage conversion module of the n^{th} battery cluster unit to be zero.
Step 3, the n^{th} BDCM coordination controller unit controls the bypass switch in the n^{th} battery cluster unit that is connected in parallel with the r^{th} bidirectional DC/DC voltage conversion module to close.
Step 4: the n^{th} BDCM coordination controller unit controls the r^{th} bidirectional DC/DC voltage conversion modules of the n^{th} battery cluster unit to turn off the output.
Step 5, the method returns to the step of calculating the total target voltage of the battery cluster, and then performs the step of starting the process control; if the total voltage of the battery cluster unit does not reach the total target voltage of the battery cluster, or the battery cluster unit has overcurrent protection, then the battery cluster unit stops operating.

Compared with the prior art, the battery topology and the control method of battery cluster for the lithium-ion battery energy storage system of the present invention have the following advantages.
(1) It is beneficial to give full play to the performance of the battery pack. Because in each battery cluster of the present invention, each battery pack is connected in parallel with the input end of one bidirectional DC/DC voltage conversion module, and then connected in series through the output end of the bidirectional DC/DC voltage conversion module; and the output end of each bidirectional DC/DC voltage conversion module is also connected in parallel with a bypass switch. This topology combined with the control method of battery cluster of the present disclosure, can realize dynamic management and control of each battery pack, and actively adjust the charging and discharging of the battery pack according to the performance of the battery pack, so that the performance of the battery pack can be fully exerted, more advantageous especially for battery packs with poor consistency, which are utilized step by step.
(2) It is helpful to improve the safety of the lithium-ion battery energy storage system. Before charging and discharging in parallel, each battery cluster unit of the present invention first goes through the calculation of the total target voltage of the battery cluster and the starting process control process. The total voltage of each battery cluster all reaches a state with very small deviation, so it can to a very large extent reduce bias current and circulating current phenomenon during parallel charging and discharging of battery clusters, thereby improving safety. At the same time, during the operation of the energy storage system, if the battery pack or the bidirectional DC/DC voltage conversion module in any battery cluster fails or reaches protection conditions, it can promptly stop the operation of the bidirectional DC/DC voltage conversion module and the battery pack by the means of closing the bypass switches that can be connected in parallel with the output end of the bidirectional DC/DC voltage conversion module, which is very beneficial to improve safety.

### BRIEF DESCRIPTION OF THE DRAWINGS

FIG. 1 is a schematic diagram of circuit connection of a battery cluster unit according to an embodiment of the present invention.

FIG. 2 is a topology diagram of parallel connection of battery clusters according to an embodiment of the present invention.

### DETAILED DESCRIPTION OF SPECIFIC EMBODIMENT

The specific embodiments of the present invention will be further described in detail below with reference to the accompanying drawings.

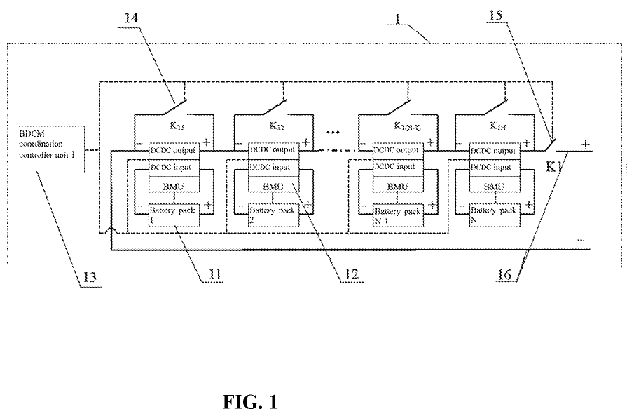

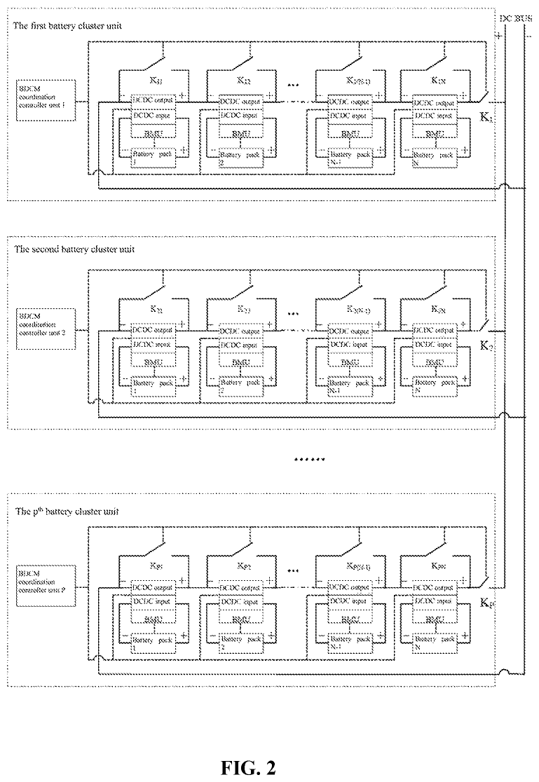

According to an embodiment of the present invention, a battery cluster topology and a control method of battery cluster for a lithium-ion battery energy storage system are provided. As shown in FIGS. 1 and 2, the battery cluster topology for the lithium-ion battery energy storage system includes P (P is a natural number greater than or equal to 2) battery cluster units 1 connected in parallel. Each battery cluster unit 1 is composed of N (N is a natural number greater than or equal to 2) battery packs 11, N bidirectional DC/DC voltage conversion modules 12, a BDCM coordination controller unit 13, N bypass switches 14, circuit switches 15, and a primary bus 16 for connection.

As shown in FIG. 1, output ends of the bidirectional DC/DC voltage conversion modules 12 are connected in series. A negative output end of the first bidirectional DC/DC voltage conversion module is connected with a negative electrode of the primary bus. A positive output end of the first bidirectional DC/DC voltage conversion module is connected with a negative output end of a second bidirectional DC/DC voltage conversion module, and a positive output end of the second bidirectional DC/DC voltage conversion module is connected with a negative output end of the third bidirectional DC/DC voltage conversion module. A positive output end of the (N−1)^{th} bidirectional DC/DC voltage conversion module is connected with a negative output end of a N^{th} bidirectional DC/DC voltage conversion module, and a negative output end of the N^{th} bidirectional DC/DC voltage conversion module is connected with one end of the circuit switch, and the other end of the circuit switch is connected with a positive electrode of the primary bus.

The N battery packs are connected in parallel with input ends of the N bidirectional DC/DC voltage conversion modules, a positive end of the first battery pack is connected with a positive input end of the first bidirectional DC/DC voltage conversion module, and a negative end of a first battery pack is connected with a negative input end of the first bidirectional DC/DC voltage conversion module, a positive end of the N^{th} battery pack is connected with a positive input end of the N^{th} bidirectional DC/DC voltage conversion module, and a negative end of the N^{th} battery pack is connected with a negative input end of the N^{th} bidirectional DC/DC voltage conversion module.

The N bypass switches are connected in parallel with output ends of the N bidirectional DC/DC voltage conversion modules. One end of the first bypass switch is connected with a negative output end of the first bidirectional DC/DC voltage conversion module. The other end of the first bypass switch is connected with a positive output end of the first bidirectional DC/DC voltage conversion module, one end of the N^{th} bypass switch is connected with a negative output end of the N^{th} bidirectional DC/DC voltage conversion module, and the other end of N^{th} bypass switch is connected with a positive output end of the N^{th} bidirectional DC/DC voltage conversion module.

The bidirectional DC/DC voltage conversion module integrates the functions of the battery management unit BMU. The BMU can calculate the state of charge, estimate the health status, and manage the battery pack safety for the battery pack. The bidirectional DC/DC voltage conversion module regulates its output voltage according to instructions of the BDCM coordination controller unit.

The bypass switch functions as a bypass bidirectional DC/DC voltage conversion module.

The BDCM coordination controller unit manages the battery cluster, including the functions like charging and discharging management of the battery cluster, calculation of the state of charge of the battery cluster, safety management of the battery cluster, controlling the bypass switch to close or open, and controlling the circuit switch to close or open; and has the function of communicating and information interaction with the outside.

In an embodiment of the present disclosure, the battery pack is composed of more than two single lithium-ion batteries connected in series, and the battery pack is integrated with an underlying management unit for voltage sampling, temperature sampling, and balancing purposes.

The BDCM coordination controller unit is connected with the bidirectional DC/DC voltage conversion module, the bypass switches, and the circuit switches through a communication bus. The battery management unit BMU of the bidirectional DC/DC voltage conversion module is communicatively connected with the underlying management unit of the battery pack.

A control method of battery cluster includes calculating a total target voltage of battery cluster, starting a process control, and stopping the process control.

The step of calculating the total target voltage of the battery cluster in the control method of battery cluster is as follows.
Step 1, the n^{th} BDCM coordination controller unit reads current voltages of all N battery packs in the n^{th} battery cluster unit, and adds voltages of the N battery pack to obtain the total voltage V_total_n of the n^{th} battery cluster unit, and n is a natural number from 1 to P.
Step 2, each BDCM coordination controller unit broadcasts the total voltage of the corresponding battery cluster unit on its communication bus. Each BDCM coordination controller unit compares the total voltage of the battery cluster unit of this battery cluster unit with those of the battery cluster units among other battery cluster units. Each BDCM coordination controller unit broadcasts the maximum value of the total voltage of the battery cluster in the battery cluster unit determined by itself on its communication bus.
Step 3, each BDCM coordination controller unit receives the maximum value of the total voltage of the battery cluster broadcast on the communication bus, and compares these results with the maximum value of the total voltage of the battery cluster determined by itself. If the results are different, then it returns to the step 1 and calculates again. If the results are the same, then it calculates the total target voltage of the battery cluster, the total target voltage of n^{th} battery cluster is V_target_cluster_n, V_target_cluster_n=V_max_cluster+a fixed limit value, where the V_max_cluster is the maximum total voltage of the battery clusters in all P battery cluster units, the fixed limit value is an allowable deviation of the total voltage of P battery clusters, and n is a natural number from 1 to P.

The step of starting the process control in the control method of the battery cluster is as follows.
Step 1, the n^{th} BDCM coordination controller unit reads the information of the battery pack and the bidirectional DC/DC voltage conversion module of the n^{th} battery cluster unit, including the state of charge of the battery pack, the voltage of the battery pack, temperature of the battery pack, and fault information of the bidirectional DC/DC voltage conversion module.
Step 2, the n^{th} BDCM coordination controller unit determines the consistency of the status of all N battery packs in the n^{th} battery cluster unit.
Step 3, if the consistency of the battery pack status of the n^{th} battery cluster unit meets the requirements, the n^{th} BDCM coordination controller unit broadcasts the output voltage V_out_n of all bidirectional DC/DC voltage conversion modules of the n^{th} battery cluster on the communication bus, and V_out_n=V_target_cluster_n/the number of all fault-free battery packs in the n^{th} battery cluster; if the consistency of the battery pack status of the n^{th} battery cluster unit does not meet the requirements, then the k^{th} bidirectional DC/DC voltage conversion module of the n^{th} battery cluster has a discharge output voltage V_dis_out_nk=V_target_cluster_n×SOCₙₖ/Σᵢ₌₁^{m}SOCₙᵢ, the k^{th} bidirectional DC/DC voltage conversion module of the n^{th} battery cluster has a charging output voltage V_ch_out_nk=V_target_cluster_n×(1−SOCₙₖ)/(m−Σᵢ₌₁^{m}SOCₙᵢ), where SOCₙₖ is the charge ratio of the k^{th} battery pack of the n^{th} battery cluster, and m is the number of all fault-free battery packs of the n^{th} battery cluster, and Σᵢ₌₁^{m}SOCₙᵢ represents the sum of the charge ratios of all m fault-free battery packs in the n^{th} battery cluster, obviously, m≤P.
Step 4, if the output voltage of one of the bidirectional DC/DC voltage conversion modules in the n^{th} battery cluster exceeds the limit value (assuming the limit value is V_out_limit), the n^{th} BDCM coordination controller unit controls the output voltage of the bidirectional DC/DC voltage conversion module to be V_out_limit. All other bidirectional DC/DC voltage conversion modules in the n^{th} battery cluster have an output voltage V_out_n=(V_target_cluster_n−V_out_limit)/(the number of all fault-free battery packs in the nt^{h} battery cluster−(subtract)1).
Step 5, the n^{th} BDCM coordination controller unit determines whether the total voltage of the n^{th} battery cluster unit reaches the total target voltage V_target_cluster_n of the n^{th} battery cluster or not. If not, it returns to the step 1. If it does, it proceeds to the charging or discharging phase. In the above steps 1 to 5, n is a natural number from 1 to P, and P is the number of battery clusters.

The step of stopping the process control in the control method of battery clusters is as follows.
Step 1, if the n^{th} BDCM coordination controller unit detects that the r^{th} battery pack of the n^{th} battery cluster unit fails, or the r^{th} battery pack reaches the charge cut-off condition, or the r^{th} battery pack reaches the discharge cut-off condition, or the r^{th} bidirectional DC/DC voltage conversion module fails, it proceeds to the next step.
Step 2, the n^{th} BDCM coordination controller unit controls the output voltage of the r^{th} bidirectional DC/DC voltage conversion module of the n^{th} battery cluster unit to be zero.
Step 3, the n^{th} BDCM coordination controller unit controls the bypass switch in the n^{th} battery cluster unit that is connected in parallel with the r^{th} bidirectional DC/DC voltage conversion module to close.
Step 4: the n^{th} BDCM coordination controller unit controls the r^{th} bidirectional DC/DC voltage conversion modules of the n^{th} battery cluster unit to turn off the output.
Step 5, the method returns to the step of calculating the total target voltage of the battery cluster, and then performs the step of starting the process control; if the total voltage of the battery cluster unit does not reach the total target voltage of the battery cluster, or the battery cluster unit has overcurrent protection, then the battery cluster unit stops operating.

The present invention is advantageous to give full play of the performance of the battery packs. In each battery cluster of the present invention, each battery pack is connected in parallel with the input end of a bidirectional DC/DC voltage conversion module, and then connected in series through the output end of the bidirectional DC/DC voltage conversion module; and the output end of each bidirectional DC/DC voltage conversion module is also connected in parallel with a bypass switch. This topology combined with the control method of the battery clusters of the present disclosure, can realize dynamic management and control of each battery pack, and actively adjust the charging and discharging of the battery pack according to the performance of the battery pack, so that the performance of the battery pack can be fully exerted, being more advantageous especially for battery packs with poor consistency, which are used step by step.

In each battery cluster of the present invention, each battery pack is connected in parallel with the input end of a bidirectional DC/DC voltage conversion module, and then connected in series through the output end of the bidirectional DC/DC voltage conversion module; and the output end of each bidirectional DC/DC voltage conversion module is also connected in parallel with a bypass switch. This topology combined with the control method of the battery clusters of the present disclosure, can realize dynamic management and control of each battery pack, and actively adjust the charging and discharging of the battery pack according to the performance of the battery pack, so that the performance of the battery pack can be fully exerted, being more advantageous especially for battery packs with poor consistency, which are used step by step.

Before charging and discharging in parallel, each battery cluster unit of the present invention first goes through the calculation of the total target voltage of the battery cluster and the starting process control process. The total voltage of each battery cluster all reaches a state with very small deviation, so it can reduce to a very large extent bias current and circulating current phenomenon during parallel charging and discharging of battery clusters, thereby improving safety. At the same time, during the operation of the energy storage system, if the battery pack or the bidirectional DC/DC voltage conversion module in any battery cluster fails or reaches protection conditions, it can promptly stop the operation of the bidirectional DC/DC voltage conversion module and the battery pack by the means of closing the bypass switches that can be connected in parallel with the output end of the bidirectional DC/DC voltage conversion module, which is very beneficial to improve safety.

What is claimed is:

1. A battery cluster topology for a lithium-ion battery energy storage system, characterized in that: the battery cluster topology for the lithium-ion battery energy storage system comprises P parallel battery cluster units (P is a natural number greater than or equal to 2), each battery cluster unit is composed of N battery packs (N is a natural number greater than or equal to 2), N bidirectional DC/DC voltage conversion modules, N bypass switches, BDCM coordination controller units, circuit switches, primary buses for connection;
output ends of the N bidirectional DC/DC voltage conversion modules are connected in series in sequence, a negative output end of the first bidirectional DC/DC voltage conversion module is connected with a negative electrode of the primary bus, and a positive output end of the first bidirectional DC/DC voltage conversion module is connected with a negative output end of the second bidirectional DC/DC voltage conversion module, a positive output end of the second bidirectional DC/DC voltage conversion module is connected with a negative output end of the third bidirectional DC/DC voltage conversion module, and a positive output end of (N−1)^{th} bidirectional DC/DC voltage conversion module is connected with a negative output end of the N^{th} bidirectional DC/DC voltage conversion module, and a negative output end of the N^{th} bidirectional DC/DC voltage conversion module is connected with one end of the circuit switch, the other end of the circuit switch is connected to a positive electrode of the primary bus;
the N battery packs are connected in parallel with input ends of the N bidirectional DC/DC voltage conversion modules, a positive end of the first battery pack is connected with a positive input end of the first bidirectional DC/DC voltage conversion module, and a negative end of the first battery pack is connected with a negative input end of the first bidirectional DC/DC voltage conversion module, a positive end of the N^{th} battery pack is connected with a positive input end of the N^{th} bidirectional DC/DC voltage conversion module, and a negative end of the N^{th} battery pack is connected with a negative input end of the N^{th} bidirectional DC/DC voltage conversion module;
the N bypass switches are connected in parallel with output ends of the N bidirectional DC/DC voltage conversion modules, one end of the first bypass switch is connected with the negative output end of the first bidirectional DC/DC voltage conversion module, the other end of the first bypass switch is connected with the positive output end of the first bidirectional DC/DC voltage conversion module, one end of the N^{th} bypass switch is connected with the negative output end of the N^{th} bidirectional DC/DC voltage conversion module, and the other end of the N^{th} bypass switch is connected with the positive output end of the N^{th} bidirectional DC/DC voltage conversion module;
the bidirectional DC/DC voltage conversion module integrates functions of the battery management unit BMU which can calculate a state of charge, estimate a health status, and manage safety of the battery pack for the battery pack, and the bidirectional DC/DC voltage conversion modules regulate its output voltage according to instructions of the BDCM coordination controller units;
the BDCM coordination controller units manage the battery cluster, having functions of charging and discharging management of the battery cluster, calculation of the state of charge of the battery cluster, safety management of the battery cluster, controlling the bypass switches to close or open, and controlling the circuit switches to close or open, and having a function of communicating and information interaction with the outside;
the control method of battery cluster comprises calculating a total target voltage of the battery cluster, starting a process control, and stopping the process control;
a key algorithm for calculating the total target voltage of battery cluster is to determine the total target voltage of n^{th} battery cluster V_target_cluster_n, V_target_cluster_n=V_max_cluster+V_con, where V_max_cluster is a maximum total voltage of battery cluster in all P battery cluster units;
n is a natural number from 1 to P; V_con is a fixed limit value, and the value of V_con satisfies: V_con≤V_DC_sum−V_max_cluster, where V_DC_sum is a sum of the output voltage limit values of all the DC/DC voltage conversion modules in the battery cluster which has the maximum total voltage among all the battery clusters;
a key algorithm of the starting the process control is to determine the output voltage of the bidirectional DC/DC voltage conversion module, when a status consistency of all fault-free battery packs in the n^{th} battery cluster is good, all bidirectional DC/DC voltage conversion modules of the n^{th} battery cluster have an output voltage V_out_n=V_target_cluster_n/m, m is the number of all fault-free battery packs in the n^{th} battery cluster; and when the status consistency of all fault-free battery packs in the n^{th} battery cluster is poor, the k^{th} bidirectional DC/DC voltage conversion module in the n^{th} battery cluster has a discharge output voltage V_dis_out_nk=V_target_cluster_n×SOCₙₖ/Σᵢ₌₁^{m}SOCₙᵢ, and the k^{th} bidirectional DC/DC voltage conversion module in the n^{th} battery cluster has a charging output voltage V_ch_out_nk=V_target_cluster_n×(1−SOCₙₖ)/(m−Σᵢ₌₁^{m}SOCₙᵢ), where SOCₙₖ is a charge ratio of the k^{th} battery pack of the n^{th} battery cluster, and m is the number of all fault-free battery packs of the n^{th} battery cluster, and Σᵢ₌₁^{m}SOCₙᵢ represents a sum of the charge ratios of all m fault-free battery packs in the n^{th} battery cluster.

2. The battery cluster topology for a lithium-ion battery energy storage system according to claim 1, characterized in that, the bypass switch functions as a bypass bidirectional DC/DC voltage conversion module; the battery pack consists of two or more single lithium-ion batteries connected in series; the BDCM coordination controller unit is connected with the bidirectional DC/DC voltage conversion module, the bypass switch, and the circuit switch through the communication bus, and the battery management unit BMU of the bidirectional DC/DC voltage conversion module is communicatively connected with an underlying management unit of the battery pack.

3. A control method of battery cluster for a lithium-ion battery energy storage system according to claim 1, characterized in that, the step of calculating the total target voltage of battery cluster in the control method of battery cluster is as follows:
Step 1, the n^{th} BDCM coordination controller unit reads current voltages of all N battery packs in the n^{th} battery cluster unit, and adds voltages of the N battery pack to obtain the total voltage V_total_n of the n^{th} battery cluster unit, n being a natural number from 1 to P;
Step 2, each BDCM coordination controller unit broadcasts the total voltage of a corresponding battery cluster unit on its communication bus, each BDCM coordination controller unit compares the total voltage of the battery cluster unit of this battery cluster unit with those of the battery cluster units among other battery cluster units, and each BDCM coordination controller unit broadcasts the maximum value of total voltage of the battery cluster in the battery cluster unit determined by itself on its communication bus; and
Step 3, each BDCM coordination controller unit receives the maximum value of the total voltage of the battery cluster broadcast on the communication bus, and compares these results with the maximum value of the total voltage of the battery cluster determined by itself, if the results are different, then it returns to the step 1 and calculates again; or if the results are the same, then it calculates the total target voltage of the battery cluster, the total target voltage of n^{th} battery cluster is_target_cluster_n, V_target_cluster_n=V_max_cluster+V_con, where the V_max_cluster is the maximum value of the total voltage of the battery clusters in all P battery cluster units, n is a natural number from 1 to P, V_con is a fixed limit value, and the value of V_con satisfies: V_con≤V_DC_sum−V_max_cluster, where V_DC_sum is a sum of the limit values of the output voltages of all bidirectional DC/DC voltage conversion modules in the battery cluster which has a maximum value of the total voltage of the battery cluster.

4. The control method of battery cluster for a lithium-ion battery energy storage system according to claim 3, characterized in that, the step of starting process control in the control method of battery cluster is as follows:
Step 1, the n^{th} BDCM coordination controller unit reads information of the battery pack and the bidirectional DC/DC voltage conversion module of the n^{th} battery cluster unit, comprising the state of charge of the battery pack, the voltage of the battery pack, temperature of the battery pack, and fault information of the bidirectional DC/DC voltage conversion module;
Step 2, the n^{th} BDCM coordination controller unit determines consistency of the status of all N battery packs in the n^{th} battery cluster unit;
Step 3, if the consistency of the battery pack status of the n^{th} battery cluster unit meets requirements, the n^{th} BDCM coordination controller unit broadcasts the output voltage V_out_n of all bidirectional DC/DC voltage conversion modules of the n^{th} battery cluster on the communication bus, and V_out_n=V_target_cluster_n/m, m is the number of all fault-free battery packs in the n^{th} battery cluster; if the consistency of the battery pack status of the n^{th} battery cluster unit does not meet the requirements, then the k^{th} bidirectional DC/DC voltage conversion module of the n^{th} battery cluster has a discharge output voltage V_dis_out_nk=V_target_cluster_n×SOCₙₖ/Σᵢ₌₁^{m}SOCₙᵢ, the k^{th} bidirectional DC/DC voltage conversion module of the n^{th} battery cluster has a charging output voltage V_ch_out_nk=V_target_cluster_n×(1−SOCₙₖ)/(m−Σᵢ₌₁^{m}SOCₙᵢ), where SOCₙₖ is the charge ratio of the k^{th} battery pack of the n^{th} battery cluster, and m is the number of all fault-free battery packs of the n^{th} battery cluster, Σᵢ₌₁^{m}SOCₙᵢ represents the sum of the charge ratios of all m fault-free battery packs in the n^{th} battery cluster, obviously, m≤P;
Step 4, if the output voltage of b bidirectional DC/DC voltage conversion modules in the n^{th} battery cluster exceeds a limit value (assuming the limit value is V_out_limit), the n^{th} BDCM coordination controller unit controls the output voltage of the bidirectional DC/DC voltage conversion module to be V_out_limit, all other bidirectional DC/DC voltage conversion modules in the n^{th} battery cluster have an output voltage V_out_n=(V_target_cluster_n−V_out_limit)÷(m−b), where m is the number of all fault-free battery packs in the n^{th} battery cluster, and b is a natural number from 1 to m; and
Step 5, the n^{th} BDCM coordination controller unit determines whether the total voltage of the n^{th} battery cluster unit reaches the total target voltage V_target_cluster_n of the n^{th} battery cluster or not, if not, it returns to the step 1, if it does, it proceeds to the charging or discharging phase;
in the above steps 1 to 5, n is a natural number from 1 to P, and P is the number of battery clusters.

5. The control method of battery cluster for a lithium-ion battery energy storage system according to claim 3, characterized in that, the step of stopping the process control in the control method of battery cluster is as follows:
Step 1, if the n^{th} BDCM coordination controller unit detects that the r^{th} battery pack of the n^{th} battery cluster unit fails, or the r^{th} battery pack reaches the charge cut-off condition, or the r^{th} battery pack reaches the discharge cut-off condition, or the r^{th} bidirectional DC/DC voltage conversion module fails, it proceeds to the next step;
Step 2, the n^{th} BDCM coordination controller unit controls the output voltage of the r^{th} bidirectional DC/DC voltage conversion module of the n^{th} battery cluster unit to be zero;
Step 3, the n^{th} BDCM coordination controller unit controls the bypass switch in the n^{th} battery cluster unit that is connected in parallel with the r^{th} bidirectional DC/DC voltage conversion module to close;
Step 4: the n^{th} BDCM coordination controller unit controls the r^{th} bidirectional DC/DC voltage conversion modules of the n^{th} battery cluster unit to turn off the output; and
Step 5, the method returns to the step of calculating the total target voltage of the battery cluster, and then performs the step of starting the process control; if the total voltage of the battery cluster unit does not reach the total target voltage of the battery cluster, or the battery cluster unit has overcurrent protection, then the battery cluster unit stops operating.
